(19) United States
(12) Patent Application Publication
(10) Pub. No.: US 2007/0249165 A1
(43) Pub. Date: Oct. 25, 2007

(54) Dual damascene process

(76) Inventors: Chun-Jen Huang, Yongkang City (TW); Cheng-Ming Weng, Jhubei City (TW); Meng-Jun Wang, Cingshuei Township (TW)

Correspondence Address: J.C. Patents, Inc., 4 Venture, Suite 250, Irvine, CA, 92618, US

(21) Appl. No.: 11/399,084

(22) Filed: Apr. 5, 2006

(51) Int. Cl. H01L 21/4763

(52) U.S. Cl. 438/638

(57) ABSTRACT

A dual damascene process is provided. A substrate having a conductive area is provided. An etching stop layer, a dielectric layer and a patterned hard mask layer are sequentially formed on the substrate. A first opening is formed in the dielectric layer exposed by the patterned hard mask layer. A first material layer having a high etching selectivity with respect to the dielectric layer is deposited to fill the first opening. A portion of the dielectric layer and the filling material layer are removed to form a trench and a second opening. The filling material layer exposed by the second opening is removed to expose part of the etching stop layer. A portion of the etching stop layer is removed to form a third opening. A conductive layer is formed in the trench and the third opening.

### BACKGROUND OF THE INVENTION

1. Field of the Invention

The present invention relates to a semiconductor fabrication process. More particularly, the present invention relates to a dual damascene process.

2. Description of the Related Art

Dual damascene process is a technique for embedding interconnects within an insulating layer. The deployment of the dual damascene process can avoid overlay error and process bias problem that results from forming metallic wires in a photolithographic process after forming a contact. Furthermore, the dual damascene process can improve the reliability of the devices and increase the productivity of the production processes. Consequently, as the level of device integration continues to increase, the dual damascene process has gradually become one of the principle techniques for forming integrated circuits in the semiconductor industry.

However, most dual damascene processes still has a number of technical problems. FIGS. 1A through 1C are schematic cross-sectional views showing the steps in a conventional dual damascene process. First, as shown in FIG. 1A, a dielectric layer 104 and a patterned hard mask layer 106 are sequentially formed over a substrate 100. The substrate 100 has a conductive area 102. The conductive area 102 is a conductive wire or an electrode, for example. Then, as shown in FIG. 1B, a patterned photoresist layer 108 is formed over the substrate 100. Thereafter, an etching operation is performed to remove a portion of the dielectric layer 104 and form an opening 110. After that, as shown in FIG. 1C, the patterned photoresist layer 108 is removed. Using the hard mask layer 106 as a mask, another etching operation is performed to remove a portion of the dielectric layer 104 and, at the same time, form a trench 112 and an opening 114 in the dielectric layer 104. The opening 114 exposes part of the conductive area 102. Next, a conductive material is deposited into the trench 112 and the opening 114 to form a conductive layer 116, thereby form a complete dual damascene structure.

In the aforementioned dual damascene process, the opening 110 is formed in the dielectric layer 104 before performing an etching operation to etch the dielectric layer 104 exposed by the patterned hard mask layer 106 and the dielectric layer 104 underneath the opening 110. Therefore, with the need to form the trench 112 and the opening 114 for exposing the conductive area 102 simultaneously, depth of the trench 112 is hard to control. This often leads to the situation of having too deep a trench 112 when the opening 114 manages to expose the conductive area 102 or having a trench 112 with the correct depth but the opening 114 has still not exposed the conductive area 102.

### SUMMARY OF THE INVENTION

Accordingly, at least one objective of the present invention is to provide a dual damascene process having a greater control on the depth of a trench when a trench and an opening are form together.

At least another objective of the present invention is to provide a dual damascene process that can produce a trench and an opening with a better profile.

To achieve these and other advantages and in accordance with the purpose of the invention, as embodied and broadly described herein, the invention provides a dual damascene process. First, a substrate having a conductive area thereon is provided. Then, an etching stop layer, a dielectric layer and a patterned hard mask layer are sequentially formed over a substrate. The patterned hard mask layer exposes a portion of the dielectric layer. Then, a first opening is formed in the dielectric layer exposed by the patterned hard mask layer. The first opening exposes a portion of the etching stop layer. Thereafter, filling material is deposited into the first opening to form a filling material layer. The surface of the filling material layer is lower than the top of the first opening. The filling material layer has a higher etching selectivity with respect to the dielectric layer. Using the patterned hard mask layer as a mask, a portion of the dielectric layer and the filling material layer are removed to form a trench and a second opening in the dielectric layer. The second opening exposes a portion of the filling material layer. After that, the exposed filling material layer is removed to expose a portion of the etching stop layer. The exposed etching stop layer is removed to form a third opening that exposes a portion of the conductive area. Then, a conductive layer is formed in the trench and the third opening.

According to the aforementioned dual damascene process in one embodiment of the present invention, the filling material layer is fabricated using photoresist or polymer, for example.

According to the aforementioned dual damascene process in one embodiment of the present invention, the method of filling the first opening with a filling material layer includes forming a material layer over the substrate. Then, the material layer is etched to remove the material layer outside the first opening and a portion of the material layer inside the first opening.

According to the aforementioned dual damascene process in one embodiment of the present invention, the method of forming the first opening includes forming a patterned photoresist layer over the substrate. The patterned photoresist layer covers the patterned hard mask layer and a portion of the dielectric layer. Then, using the patterned photoresist layer as a mask, a portion of the dielectric layer is removed to expose a portion of the etching stop layer.

According to the aforementioned dual damascene process in one embodiment of the present invention, the etching stop layer is fabricated using silicon carbonitride, for example.

According to the aforementioned dual damascene process in one embodiment of the present invention, the dielectric layer is fabricated using a low dielectric constant material, for example.

According to the aforementioned dual damascene process in one embodiment of the present invention, the patterned hard mask layer is fabricated using titanium, titanium nitride, tantalum, tantalum nitride or tungsten nitride, for example.

According to the aforementioned dual damascene process in one embodiment of the present invention, the conductive layer is fabricated using copper, for example.

According to the aforementioned dual damascene process in one embodiment of the present invention, after forming the dielectric layer but before forming the patterned hard mask layer, further includes forming a cap layer over the dielectric layer.

According to the aforementioned dual damascene process in one embodiment of the present invention, after forming the patterned hard mask layer but before forming the first opening, further includes forming an anti-reflection layer over the patterned hard mask layer.

According to the aforementioned dual damascene process in one embodiment of the present invention, after forming the third opening but before forming the conductive layer, further includes forming a barrier layer over the surface of the trench and the third opening.

According to the aforementioned dual damascene process in one embodiment of the present invention, the conductive area includes a conductive wire or an electrode, for example.

The present invention also provides another dual damascene process. First, a substrate having a conductive area thereon is provided. Then, an etching stop layer, a dielectric layer and a patterned hard mask layer are sequentially formed over a substrate. The patterned hard mask layer exposes a portion of the dielectric layer. Then, a patterned photoresist layer is formed over the substrate. The patterned photoresist layer covers the patterned hard mask layer and a portion of the dielectric layer. Thereafter, using the patterned photoresist layer as a mask, a portion of the dielectric layer is removed to form a first opening. The first opening exposes a portion of the etching stop layer. After that, a material layer is formed over the substrate. Then, a back etching process is performed to remove the material layer outside the first opening and a portion of the material layer inside the first opening so that a filling material layer is formed in the first opening. The surface of the filling material layer is lower than the top of the first opening. Next, using the patterned hard mask layer as a mask, a portion of the dielectric layer and a portion of the filling material layer are removed so that a trench and a second opening are formed in the dielectric layer. The filling material layer has a removing rate higher than the dielectric layer and the second opening exposes a portion of the filling material layer. Thereafter, the exposed filling material layer is removed to expose a portion of the etching stop layer. Then, the exposed etching stop layer is removed to form a third opening. After that, a conductive layer is formed in the trench and the third opening.

According to the aforementioned dual damascene process in one embodiment of the present invention,. the filling material layer is fabricated using photoresist or polymer, for example.

According to the aforementioned dual damascene process in one embodiment of the present invention, the etching stop layer is fabricated using silicon carbonitride, for example.

According to the aforementioned dual damascene process in one embodiment of the present invention, the dielectric layer is fabricated using a low dielectric constant material, for example.

According to the aforementioned dual damascene process in one embodiment of the present invention, the patterned hard mask layer is fabricated using titanium, titanium nitride, tantalum, tantalum nitride or tungsten nitride, for example.

According to the aforementioned dual damascene process in one embodiment of the present invention, the conductive layer is fabricated using copper, for example.

According to the aforementioned dual damascene process in one embodiment of the present invention, after forming the dielectric layer but before forming the patterned hard mask layer, further includes forming a cap layer over the dielectric layer.

According to the aforementioned dual damascene process in one embodiment of the present invention, after forming the patterned hard mask layer but before forming the first opening, further includes forming an anti-reflection layer over the patterned hard mask layer.

According to the aforementioned dual damascene process in one embodiment of the present invention, after forming the third opening but before forming the conductive layer, further includes forming a barrier layer over the surface of the trench and the third opening.

According to the aforementioned dual damascene process in one embodiment of the present invention, the conductive area includes a conductive wire or an electrode, for example.

In the present invention, a first opening that exposes the etching stop layer is formed in a dielectric layer first. When the dielectric layer and the filling material layer inside the first opening is simultaneously etched to form the trench and the second opening, one only has to etch the trench to a predefined depth. A portion of the filing material layer can be retained to protect the etching stop layer exposed by the first opening. Hence, depth of the trench is much easier to control and there is no need to consider the depth of both the trench and the second opening in the etching process at the same time.

In addition, the filling material layer has an etching rate higher than the dielectric layer. Therefore, in the process of etching both the dielectric layer and the filling material layer in the first opening, the height level of the filling material layer is always lower than the height level of the dielectric layer. As a result, the formation of a fence inside the trench can be avoided and a trench and an opening with a better profile can be produced. Ultimately, the subsequently formed barrier layer can have a better coverage.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1C are schematic cross-sectional views showing the steps in a conventional dual damascene process.

FIGS. 2A through 2E are schematic cross-sectional views showing the steps in a dual damascene process according to one embodiment of the present invention.

FIG. 3 is a schematic cross-sectional view showing fences formed inside a trench in a dual damascene process.

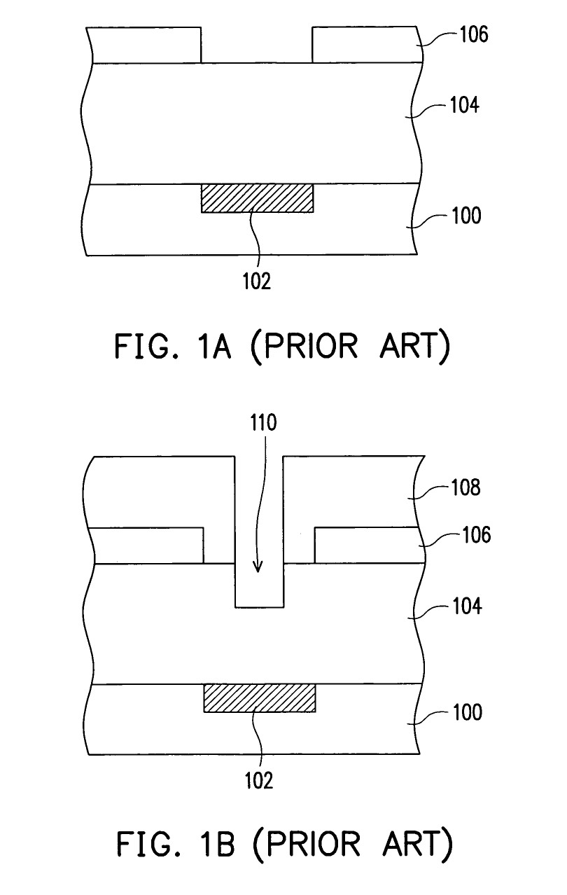

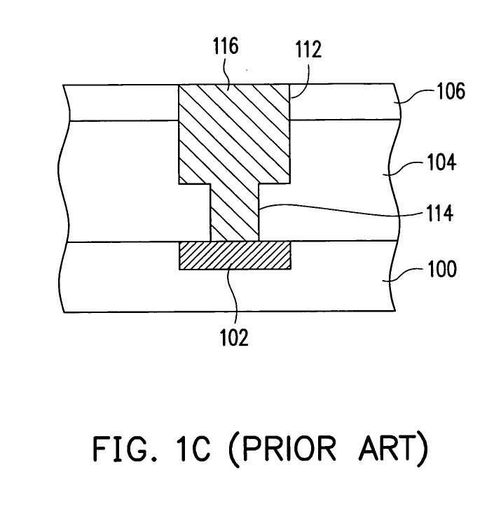

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

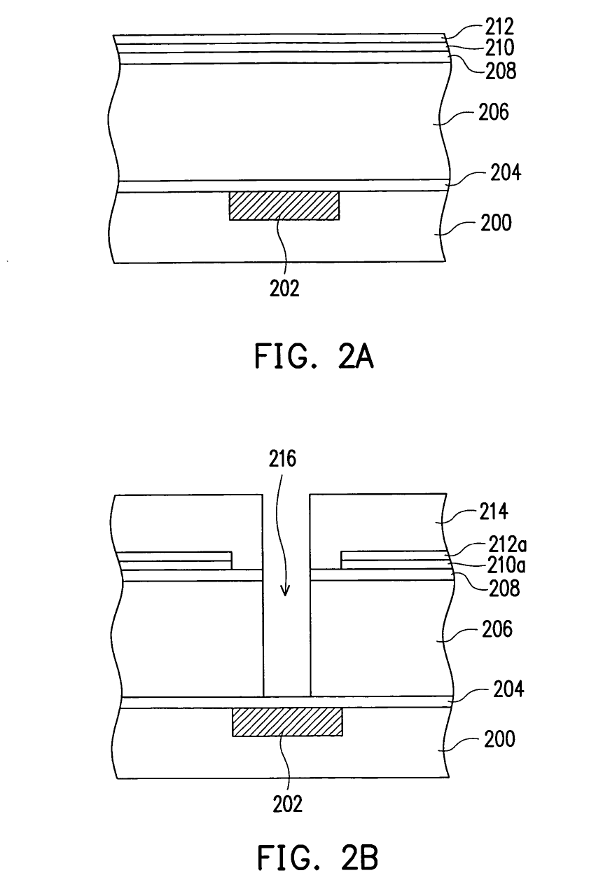

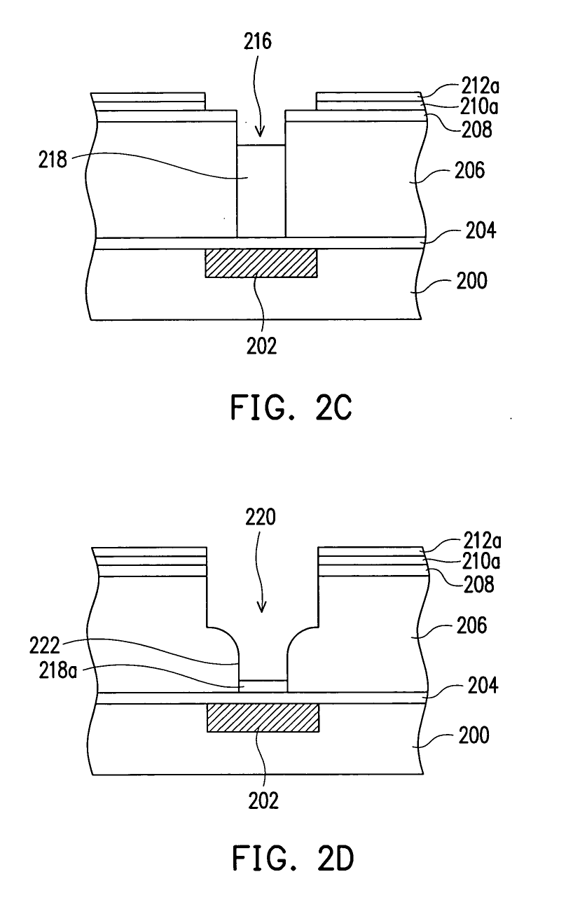

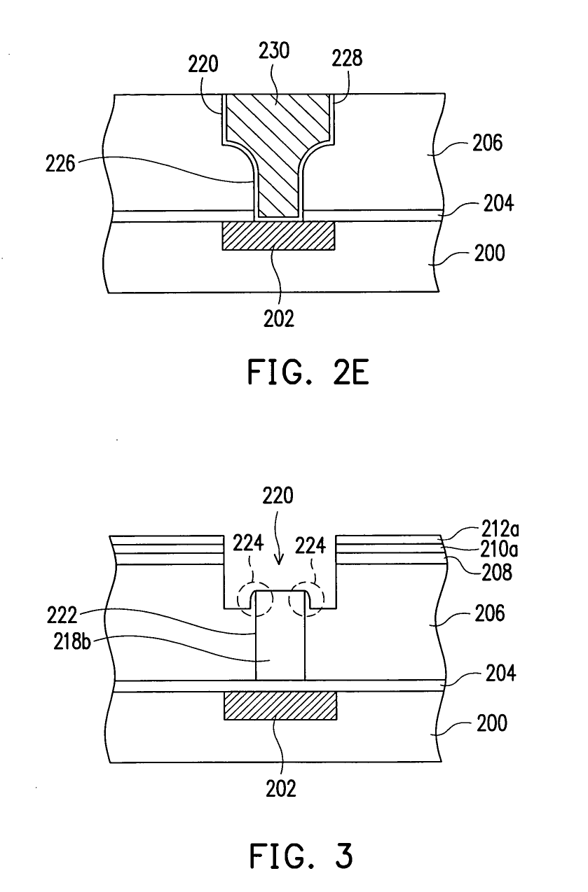

FIGS. 2A through 2E are schematic cross-sectional views showing the steps in a dual damascene process according to one embodiment of the present invention. First, as shown in FIG. 2A, a substrate 200 having a conductive area 202 thereon is provided. The conductive area 202 is a conductive wire or an electrode formed in a conventional interconnection process, for example. Then, an etching stop layer 204 is formed over the substrate 200. The etching stop layer 204 is a silicon carbonitride layer formed by performing a chemical vapor deposition (CVD) process. Thereafter, a dielectric layer 206 is formed over the etching stop layer 204. The dielectric layer 206 is formed using a low dielectric constant material (with a dielectric constant k<4), for example. The low dielectric constant material includes an inorganic material such as hydrogen silsesquioxane (HSQ) or fluorinated silicate glass (FSG), or an organic material such as fluorinated poly-(arylene ether), Flare), poly-(arylene ether), SILK) or parylene. The dielectric layer 206 is formed in a chemical vapor deposition process, for example.

Thereafter, a hard mask layer 210 is formed over the dielectric layer 206. The hard mask layer 210 is a metallic hard mask layer fabricated using titanium, titanium nitride, tantalum, tantalum nitride or tungsten nitride, for example. The hard mask layer 210 is formed, for example, by performing a chemical vapor deposition process or a physical vapor deposition process. In addition, after forming the dielectric layer 206 but before forming the hard mask layer 210, a cap layer 208 can also be selectively formed over the dielectric layer 206. The cap layer 208 is a plasma-enhanced oxide (PEOX), for example. The cap layer 208 may serve as a polishing stop layer in a subsequent chemical-mechanical polishing process and prevent any damage to the underlying dielectric layer 206. Furthermore, after forming the hard mask layer 210, an anti-reflection layer 212 can also be selectively formed over the hard mask layer 210 to prevent the surface of the hard mask layer 210 from reflecting any light in a subsequent patterning operation and affecting the pattern transfer accuracy. The anti-reflection layer 210 can be a silicon oxynitride layer or other anti-reflection material layer formed by performing a chemical vapor deposition (CVD) process, for example.

As shown in FIG. 2B, the anti-reflection layer 212 and the hard mask layer 210 is patterned to form a patterned anti-reflection layer 212a and a patterned hard mask layer 210a that expose a portion of the cap layer 208. The anti-reflection layer 212 and the hard mask layer 210 is patterned, for example, by forming a patterned photoresist layer (not shown) over the anti-reflection layer 212 such that the patterned photoresist layer is disposed above the conductive area 202. Then, using the patterned photoresist layer as a mask, a portion of the anti-reflection layer 212 and the hard mask layer 210 are removed to expose the surface of the cap layer 208. Thereafter, the patterned photoresist layer is removed.

Next, another patterned photoresist layer 214 is formed over the substrate 200. The patterned photoresist layer 214 covers the patterned anti-reflection layer 212a and a portion of the cap layer 208. Then, using the patterned photoresist layer 214 as a mask, a portion of the cap layer 208 and the dielectric layer 206 are removed to form an opening 216 that exposes a portion of the etching stop layer 204.

Thereafter, as shown in FIG. 2C, the patterned photoresist layer 214 is removed. Then, filling material is deposited into the opening 216 to form a filling material layer 218. The surface of the filling material layer 218 is below the top of the opening 216. The filling material layer 218 has a high etching selectivity with respect to the dielectric layer 206. The filling material layer 218 can be a photoresist layer or a polymer layer, for example. The method of forming the filling material layer 218 includes forming a material layer (not shown) over the substrate 200 by performing a chemical vapor deposition process, for example. Then, the material layer is etched back to remove the material layer outside the opening 216 and a portion of the material layer inside the opening 216 so that the filling material layer 218 is formed within the opening 216.

As shown in FIG. 2D, using the patterned anti-reflection layer 212a and the patterned hard mask layer 201 a as a mask, a portion of the cap layer 208, a portion of the dielectric layer 206 and a portion of the filling material layer 218 are removed. Hence, a trench 220 and an opening 222 are formed in the dielectric layer 206 and a filling material layer 218a is formed at the bottom of the opening 222. Because the opening 216 has already been made to expose a portion of the etching stop layer 204 in a previous step, only depth of the trench 220 needs to be controlled in the process of forming the trench 220. Since there is no need to consider whether the opening 222 has a sufficient depth to expose a portion of the etching stop layer 204 or not, it will be easier to control the depth of the trench 220 to a predefined value. Furthermore, the filling material layer 218 is not completely removed in the process so that a portion of the filling material layer 218a remains at the bottom of the opening 222. The filling material layer 218a protects the underlying etching stop layer 204 and prevents the etching stop layer 204 from a partial or complete removal. Ultimately, the subsequent processes can have a better control.

It should be noted that the filling material layer 218 has a higher removing rate than the dielectric layer 206 in the process of forming the trench 220 and the opening 222. Thus, the trench 220 and the opening 222 can have a better profile without forming any fences. FIG. 3 is a schematic cross-sectional view showing fences formed inside a trench in a dual damascene process. As shown in FIG. 3, assume that the rate of removal of the filling material layer 218 is smaller than the rate of removal of the dielectric layer 206 in the process of forming the trench 220 in the dielectric layer 206. The surface of the filling material layer 218b after removing a portion of the cap layer 208, a portion of the dielectric layer 206 and a portion of the filling material layer 218 will be higher than the bottom of the trench 220. As a result, fences 224 will be formed on a portion of the sidewall of the filling material layer 218b. These fences 224 often lead to a poor coverage of the subsequently formed barrier layer and result in a drop in the performance and the reliability of the device.

Thereafter, as shown in FIG. 2E, the filling material layer 218a exposed by the opening 222 is removed to expose a portion of the etching stop layer 204. Then, the exposed etching stop layer 204 is removed to form an opening 226. Thereafter, other conventional processes necessary for forming the dual damascene structure are subsequently carried out and a conductive layer 230 is formed in the trench 220 and the opening 226. The conductive layer 230 can be a copper or other metallic layer formed, for example, by depositing a conductive material layer over the substrate 200 in a chemical vapor deposition process and removing the conductive material layer outside the trench 220 and the opening 226. The method of removing the conductive material layer outside the trench 220 and the opening 226 includes performing a chemical-mechanical polishing operation, for example. Moreover, after forming the opening 226 but before forming the conductive layer 230, a barrier layer 228 may also be selectively formed on the surface of the trench 220 and the opening 226. The barrier layer 228 can be a titanium nitride layer or a tantalum nitride layer formed, for example, by performing a chemical vapor deposition (CVD) process. The barrier layer 228 can be used to enhance the adhesive strength of the conductive layer 230.

In summary, the dual damascene process in the present invention includes forming an opening that exposes the etching stop layer in a dielectric layer first and filling the opening to form a filling material layer having a higher etching selectivity relative to the dielectric layer thereafter. Hence, one only has to consider whether the trench has reached a predefined depth in the process of forming the trench. Because there is no need to consider whether the opening has exposed the etching stop layer or not, it is easier to control the depth of the trench. Moreover, a portion of the filling material layer is retained on the etching stop layer after forming the trench so that the etching stop layer is prevented from a partial or complete removal. As a result, the control of subsequent processes is substantially facilitated.

In addition, the filling material layer has an etching rate higher than the dielectric layer in the process of removing a portion of the filling material layer and a portion of the dielectric layer. Therefore, in the removing process, the height level of the filling material layer is always lower than the height level of the dielectric layer. As a result, the formation of a fence inside the trench can be avoided and a trench and an opening with a better profile can be produced. Ultimately, the subsequently formed barrier layer can have a better coverage and the device can have a better performance and reliability.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A dual damascene process, comprising the steps of:
providing a substrate having a conductive area thereon;
forming an etching stop layer, a dielectric layer and a patterned hard mask layer in sequence over the substrate, wherein the patterned hard mask layer exposes a portion of the dielectric layer;
forming a first opening in the dielectric layer exposed by the patterned hard mask layer, wherein the first opening exposes a portion of the etching stop layer;
depositing filling material into the first opening to form a filling material layer, wherein the surface of the filling material layer is lower than the top of the first opening, and the filling material layer has a higher etching selectivity with respect to the dielectric layer;
removing a portion of the dielectric layer and a portion of the filling material layer using the hard mask layer as a mask to form a trench and a second opening in the dielectric layer, wherein the second opening exposes a portion of the filling material layer;
removing the exposed filling material layer to expose a portion of the etching stop layer;
removing the exposed etching stop layer to form a third opening that exposes a portion of the conductive area; and
forming a conductive layer in the trench and the third opening.

2. The dual damascene process of claim 1, wherein the filling material layer includes a photoresist layer or a polymer layer.

3. The dual damascene process of claim 1, wherein the step of depositing filling material into the first opening includes:
forming a material layer over the substrate; and
performing a back etching operation to remove the material layer outside the first opening and a portion of the material layer inside the first opening.

4. The dual damascene process of claim 1, wherein the step of forming the first opening includes:
forming a patterned photoresist layer over the substrate, wherein the patterned photoresist layer covers the patterned hard mask layer and a portion of the dielectric layer; and
removing a portion of the dielectric layer using the patterned photoresist layer as a mask to expose a portion of the etching stop layer.

5. The dual damascene process of claim 1, wherein the material constituting the etching stop layer includes silicon carbonitride.

6. The dual damascene process of claim 1, wherein the material constituting the dielectric layer includes a low dielectric constant substance.

7. The dual damascene process of claim 1, wherein the material constituting the patterned hard mask layer includes titanium, titanium nitride, tantalum, tantalum nitride or tungsten nitride.

8. The dual damascene process of claim 1, wherein the material constituting the conductive layer includes copper.

9. The dual damascene process of claim 1, wherein after forming the dielectric layer but before forming the patterned hard mask layer, further includes forming a cap layer over the dielectric layer.

10. The dual damascene process of claim 1, wherein after forming the patterned hard mask layer but before forming the first opening, further includes forming an anti-reflection layer over the patterned hard mask layer.

11. The dual damascene process of claim 1, wherein after forming the third opening but before forming the conductive layer, further includes forming a barrier layer on the surface of the trench and the third opening.

12. The dual damascene process of claim 1, wherein the conductive area includes a conductive wire or an electrode.

13. A dual damascene process, comprising the steps of:
providing a substrate having a conductive area thereon;
forming an etching stop layer, a dielectric layer and a patterned hard mask layer in sequence over the substrate, wherein the patterned hard mask layer exposes a portion of the dielectric layer;
forming a patterned photoresist layer over the substrate, wherein the patterned photoresist layer covers the patterned hard mask layer and a portion of the dielectric layer;
removing a portion of the dielectric layer using the patterned photoresist layer as a mask to form a first opening, wherein the first opening exposes a portion of the etching stop layer;
forming a material layer over the substrate;
performing a back etching operation to remove the material layer outside the first opening and a portion of the material layer inside the first opening to form a filling material layer in the first opening, wherein the surface of the filling material layer is lower than the top of the first opening;
removing a portion of the dielectric layer and a portion of the filling material layer using the patterned hard mask layer as a mask to form a trench and a second opening in the dielectric layer, wherein the filling material layer has a removing rate higher than the dielectric layer, and the second opening exposes a portion of the filling material layer;
removing the exposed filling material layer to expose a portion of the etching stop layer;
removing the exposed etching stop layer to form a third opening; and
forming a conductive layer in the trench and the third opening.

14. The dual damascene process of claim 13, wherein the filling material layer includes a photoresist layer or a polymer layer.

15. The dual damascene process of claim 13, wherein the material constituting the etching stop layer includes silicon carbonitride.

16. The dual damascene process of claim 13, wherein the material constituting the dielectric layer includes a low dielectric constant substance.

17. The dual damascene process of claim 13, wherein the material constituting the patterned hard mask layer includes titanium, titanium nitride, tantalum, tantalum nitride or tungsten nitride.

18. The dual damascene process of claim 13, wherein the material constituting the conductive layer includes copper.

19. The dual damascene process of claim 13, wherein after forming the dielectric layer but before forming the patterned hard mask layer, further includes forming a cap layer over the dielectric layer.

20. The dual damascene process of claim 13, wherein after forming the patterned hard mask layer but before forming the first opening, further includes forming an anti-reflection layer over the patterned hard mask layer.

21. The dual damascene process of claim 13, wherein after forming the third opening but before forming the conductive layer, further includes forming a barrier layer on the surface of the trench and the third opening.

22. The dual damascene process of claim 13, wherein the conductive area includes a conductive wire or an electrode.
